(19) United States
(12) Patent Application Publication
(10) Pub. No.: US 2010/0176796 A1
(43) Pub. Date: Jul. 15, 2010

(54) Apparatus for testing electrical characteristics

(76) Inventors: Dong-dae Kim, Yongin-si (KR); Min-gu Kim, Yongin-si (KR); Ho-jeong Choi, Yongin-si (KR); Young-soo An, Yongin-si (KR); Yang-gi Kim, Hwaseong-si (KR)

Correspondence Address: LEE & MORSE, P.C., 3141 FAIRVIEW PARK DRIVE, SUITE 500, FALLS CHURCH, VA, 22042, US

(21) Appl. No.: 12/654,955

(22) Filed: Jan. 11, 2010

(30) Foreign Application Priority Data
Jan. 13, 2009 (KR) 10-2009-0002707

(51) Int. Cl. G01R 1/06

(52) U.S. Cl. 324/149

(57) ABSTRACT

An apparatus for testing electrical characteristics includes a probe configured to contact a test object, a DC signal transmission line configured to transmit a DC signal to the probe, a frequency signal transmission line configured to transmit a frequency signal to the probe, and a line selection unit configured to selectively connect only one of the frequency signal transmission line and the DC signal transmission line to the probe at a time in accordance with a selected test.

### BACKGROUND

1. Field

Example embodiments relate to an apparatus for testing electrical characteristics. More particularly, example embodiments relate to an apparatus for testing electrical characteristics that is designed to test both direct current (DC) characteristics and frequency characteristics of a device.

2. Description of the Related Art

In general, in order to test electrical characteristics of a semiconductor device, e.g., a memory or a micro-processor, or a precision electronic device, e.g., a display device, an apparatus for testing electrical characteristics of the device via a probe may be used. For example, an operator may install a conventional testing apparatus on a test object, e.g., to perform a DC characteristics test.

### SUMMARY

Embodiments are directed to an apparatus for testing electrical characteristics, which substantially overcomes one or more of the problems due to the limitations and disadvantages of the related art.

It is therefore a feature of an embodiment to provide an apparatus having a structure configured to test both DC and frequency characteristics of a device, thereby reducing manufacturing costs of the testing apparatus.

It is therefore another feature of an embodiment to provide an apparatus configured to test both DC and frequency characteristics of a device without signal interference between a DC signal transmission line and a frequency signal transmission line, thereby improving the performance and reliability of the device.

At least one of the above and other features and advantages may be realized by providing an apparatus for testing electrical characteristics, including a probe for contacting a test object, a DC signal transmission line for transmitting a DC signal to the probe to test DC characteristics of the test object, a frequency signal transmission line for transmitting a frequency signal to the probe to test frequency characteristics of the test object, and a line selection unit configured to selectively connect only one of the frequency signal transmission line and the DC signal transmission line to the probe at a time in accordance with a selected test.

The line selection unit may include a first terminal electrically connected to the probe, a second terminal electrically connected to the DC signal transmission line and electrically contacting the first terminal, and a third terminal electrically connected to the frequency signal transmission line and contacting the first terminal to be electrically connected to the first terminal and to block electrical connection between the first terminal and the second terminal.

The first terminal may be a bar-type terminal connected to the probe and set in a circuit substrate on which the probe is installed, the second terminal may be an elastic terminal electrically connected to a DC signal transmission pattern formed in the circuit substrate, wherein the second terminal has restoring force toward the bar-type terminal so that the second terminal is elastically contacted to the bar-type terminal, and the third terminal may be a pipe type terminal that is installed on a detachable assembly that is assembled using the circuit substrate and a detachable instrument, wherein, when the detachable assembly is attached to the circuit substrate, the third terminal is selectively inserted between the bar-type terminal and the elastic terminal to block electrical connection between the bar-type terminal and the elastic terminal, and the third terminal includes a conductive body corresponding to the bar-type terminal so that the third terminal is electrically connected to the bar-type terminal, and an insulating body corresponding to the elastic terminal.

The first terminal may be a button type terminal that is connected to the probe installed on the circuit substrate, and is extended or contracted according to an elastic spring, and the second terminal may be a box type terminal that is electrically connected to a DC signal transmission pattern formed in the circuit substrate and surrounds the button type terminal, wherein an electrical contact portion is formed on an inner wall of the second terminal, corresponding to the button type terminal extended and is electrically contacted to the button type terminal when the button type terminal is extended, and wherein an insulating layer is formed on an inner wall of the second terminal corresponding to the button type terminal contracted and blocks electrical connection between the button type terminal and the second terminal when the button type terminal is contracted, and the third terminal may be a press terminal that is installed on a detachable assembly that is assembled by using the circuit substrate and a detachable instrument, and when the detachable assembly is attached to the circuit substrate, the press terminal presses the button type terminal to contract the button type terminal.

The apparatus may further include a tester head that is selectively connected to the circuit substrate and the detachable assembly, wherein a second DC signal transmission line for contacting a contact pad of the DC signal transmission line of the second terminal and the frequency signal transmission line for contacting the third terminal are installed in the tester head.

The detachable instrument may be a coupling block that is engaged with a hooking groove of a socket mold installed on the circuit substrate, and maintains the engaged state with the hooking groove via the restoring force of a spring.

The line selection unit may be a selection circuit unit that receives a selection signal of a control unit and electrically activates the DC signal transmission line or the frequency signal transmission line.

The apparatus may further include a third terminal insertion unit that selectively inserts the third terminal between the first terminal and the second terminal.

The line selection unit may include a first terminal through a circuit substrate, a first end of the first terminal being electrically connected to the probe, and a second end of the first terminal being selectively connected to the frequency signal transmission line, and a DC signal transmission pattern in the circuit substrate, the signal transmission pattern being selectively connected to the first terminal, only one of the frequency signal transmission line and the DC signal transmission pattern being electrically connected to the first terminal at a time in accordance with the selected test. The apparatus may further include a second terminal in the circuit substrate electrically connected to the DC signal transmission pattern and the first terminal, and a third terminal configured to selectively disconnect the electrical connection between the first and second terminals in accordance with the selected test, the third terminal being configured to connect the first terminal to the frequency signal transmission line upon electrical disconnection between the first and second terminals.

The third terminal may include a conductive layer and an insulting layer, the insulating layer being between the first and second terminals when the first terminal and the conductive layer of the third terminal electrically contact each other. The second terminal may include a conductive tube and an insulting tube concentric to each other, the insulating tube being between the first terminal and the conductive tube of the second terminal when the first and third terminals electrically contact each other. The second and third terminals may include an insulating layer configured to electrically disconnect the first and second terminals. The third terminal may be on an opposing surface than the first and second terminals.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a side cross-sectional view of an electrical characteristics testing apparatus in a preparation state of a DC characteristics test according to an embodiment;

FIG. 2 illustrates a side cross-sectional view of the electrical characteristics testing apparatus of FIG. 1 in an execution state of the DC characteristics test;

FIG. 3 illustrates a side cross-sectional view of the electrical characteristics testing apparatus of FIG. 1 in a preparation state of a frequency characteristics test;

FIG. 4 illustrates a side cross-sectional view of the electrical characteristics testing apparatus of FIG. 1 in an execution state of the frequency characteristics test;

FIG. 5 illustrates a side cross-sectional view of an electrical characteristics testing apparatus in a preparation state of a DC characteristics test according to another embodiment;

FIG. 6 illustrates a side cross-sectional view of the electrical characteristics testing apparatus of FIG. 5 in an execution state of the DC characteristics test;

FIG. 7 illustrates a side cross-sectional view of the electrical characteristics testing apparatus of FIG. 5 in a preparation state of a frequency characteristics test;

FIG. 8 illustrates a side cross-sectional view of the electrical characteristics testing apparatus of FIG. 5 in an execution state of the frequency characteristics test;

FIG. 9 illustrates a side cross-sectional view of an electrical characteristics testing apparatus according to another embodiment; and

FIG. 10 illustrates a side cross-sectional view of an electrical characteristics testing apparatus according to another embodiment.

### DETAILED DESCRIPTION

Korean Patent Application No. 10-2009-0002707, filed on Jan. 13, 2009, in the Korean Intellectual Property Office, and entitled: “Apparatus for Testing Electrical Characteristics,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

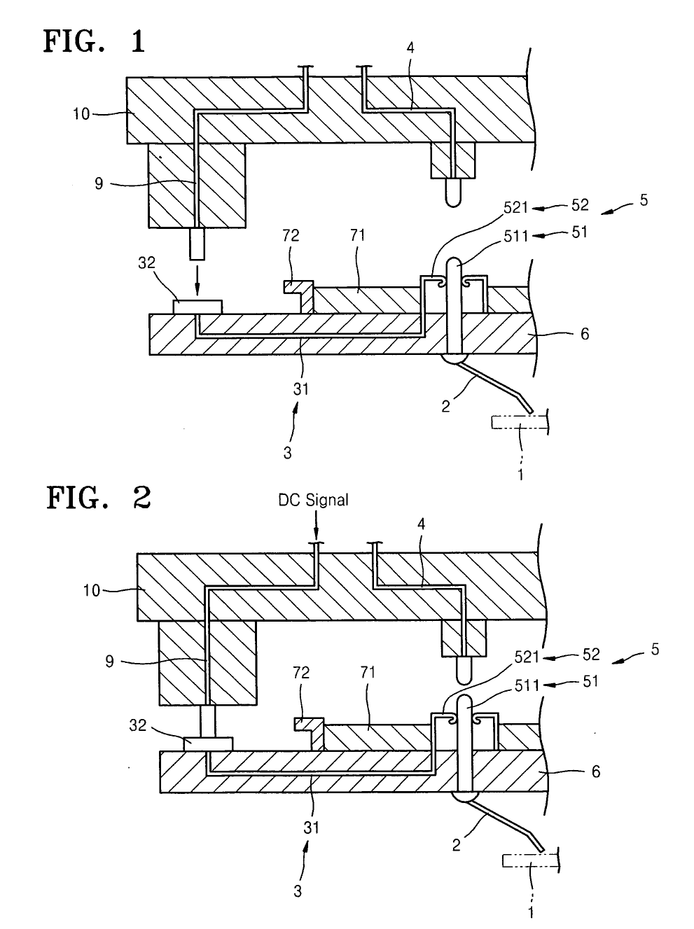

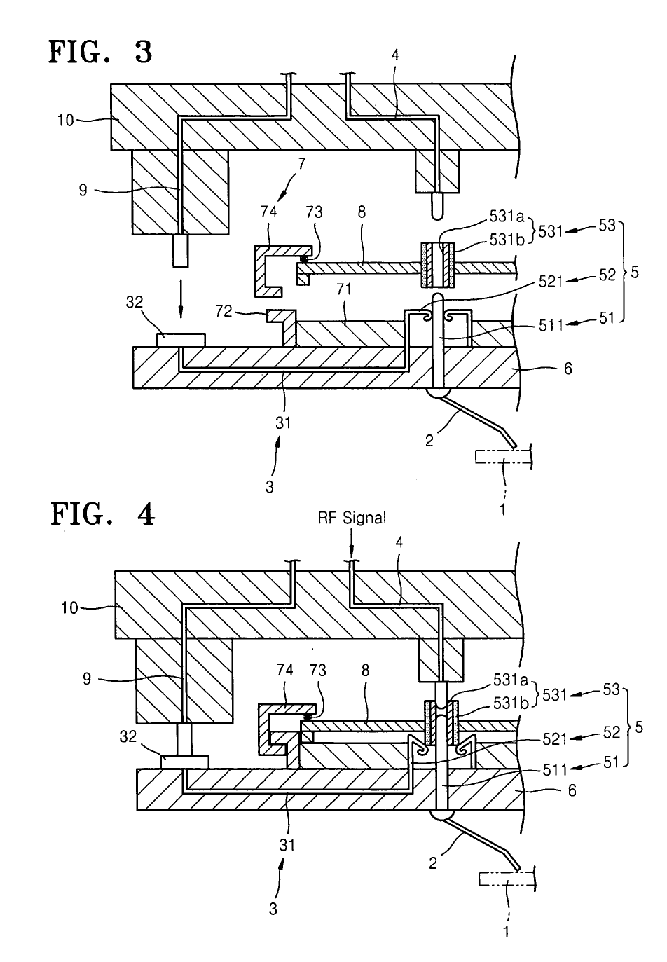

FIG. 1 illustrates a side cross-sectional view of an electrical characteristics testing apparatus in a preparation state of a DC characteristics test according to an embodiment. FIG. 2 illustrates a side cross-sectional view of the electrical characteristics testing apparatus of FIG. 1 in an execution state of the DC characteristics test. FIG. 3 illustrates a side cross-sectional view of the electrical characteristics testing apparatus of FIG. 1 in a preparation state of a frequency characteristics test. FIG. 4 illustrates a side cross-sectional view of the electrical characteristics testing apparatus FIG. 1 in an execution state of the frequency characteristics test.

As illustrated in FIGS. 1 through 4, the electric characteristics testing apparatus according to an embodiment may include a probe 2, a DC signal transmission line 3, a frequency signal transmission line 4, and a line selection unit 5.

The probe 2 may be installed on a circuit substrate 6, and may contact a test object 1, e.g., the probe 2 may be connected between the circuit substrate 6 and the test object 1. For example, the test object 1 may be a semiconductor device (e.g., memory or micro-processor) or a display device. A DC signal or a radio frequency (RF) signal may be applied to the probe 2.

The DC signal transmission line 3 may transmit a DC signal to the probe 2 in order to test DC characteristics of the test object 1. The DC signal transmission line 3 may have any suitable configuration, e.g., the DC signal transmission line 3 may include a DC transmission pattern 31 disposed in the circuit substrate 6.

The frequency signal transmission line 4 may transmit a RF signal to the probe 2 in order to test frequency characteristics of the test object 1. The frequency signal transmission line 4 may have any suitable configuration, e.g., the frequency signal transmission line 4 may be disposed in a tester head 10.

The line selection unit 5 may be configured to electrically connect either the DC signal transmission line 3 to the probe 2 or the frequency signal transmission line 4 to the probe 2. In other words, the line selection unit 5 may not connect the frequency signal transmission line 4 to the probe 2 if the DC signal transmission line 3 is connected to the probe 2. Similarly, the line selection unit 5 may not connect the DC signal transmission line 3 to the probe 2 if the frequency signal transmission line 4 is connected to the probe 2. The line selection unit 5 may include a first terminal 51, a second terminal 52, and a third terminal 53.

As illustrated in FIGS. 1-4, the first terminal 51 may be electrically connected to the probe 2. The first terminal 51 may include a bar-type terminal 511 in the circuit substrate 6 that is connected to the probe 2. For example, the bar-type terminal 511 may extend through the circuit substrate 6, e.g., through an entire thickness of the circuit substrate 6. A first end of the bar-type terminal 511 may electrically contact the probe 2 on a lower surface of the circuit substrate 6, and a second end of the bar-type terminal 511, i.e., an end opposite the first and, may extend through an upper surface, i.e., a surface opposite the lower surface, of the circuit substrate 6.

As illustrated in FIGS. 1-4, the second terminal 52 may be electrically connected to the DC signal transmission line 3. The second terminal 52 may include an elastic terminal 521 electrically connected to the DC signal transmission pattern 31 formed in the circuit substrate 6. The elastic terminal 521 may include an elastic material, and may be elastically biased toward the bar-type terminal 511. Therefore, the elastic terminal 521 may elastically contact the bar-type terminal 511. In other words, as illustrated in FIG. 3, one end of the elastic terminal 521 may be electrically connected to the DC signal transmission line 3 and another end of the elastic terminal may contact the first terminal 51.

As illustrated in FIGS. 3 and 4, the third terminal 53 may be electrically connected to the frequency signal transmission line 4. During operation, the third terminal 53 may simultaneously connect, i.e., electrically, to the first terminal 51 and block the electrical connection between the first terminal 51 and the second terminal 52. A pipe-type terminal 531 may be used as the third terminal 53.

The pipe-type terminal 531, as illustrated in FIGS. 3 and 4, may include a conductive body 531a corresponding to the bar-type terminal 511 and an insulating body 531b corresponding to the elastic terminal 521. For example, the conductive body 531a and the insulating body 531b may be two concentric tubes, and the insulating body 521b may be an outer tube on, e.g., directly on, the conductive body 531a, i.e., the conductive body 531a may have a smaller inner perimeter than the insulating body 531b. For example, the inner perimeter of the conductive body 531a may substantially equal a perimeter of the bar-type terminal 511, so the bar-type terminal 511 may be inserted into the conductive body 531a to establish electrical connection therebetween during operation. When the bar-type terminal 511 is inserted into the conductive body 531a, the insulating body 531b on the conductive body 531a may separate the second terminal 52 from the first terminal 51, as illustrated in FIG. 4.

For example, as illustrated in FIG. 4, when the third terminal 53 is installed on a detachable assembly 8 that is attached to the circuit substrate 6 via a detachable instrument 7, the third terminal 53 may be selectively inserted between the bar-type terminal 511 and the elastic terminal 521 to block electrical connection therebetween and to connect the third terminal 53 to the bar-type terminal 511. As illustrated in FIGS. 3 and 4, the first terminal 51 and the second terminal 52 may be installed on the circuit substrate 6, and the third terminal 53 may be installed on the detachable assembly 8, which is assembled by using the circuit substrate 6 and the detachable instrument 7.

As illustrated in FIGS. 1-4, the electric characteristics testing apparatus according to an embodiment may further include a tester head 10 that selectively contacts the detachable assembly 8 attached to the circuit substrate 6. That is, the tester head 10 may be selectively connected to the circuit substrate 6 and the detachable assembly 8, such that the detachable assembly 8 may be in a space between the circuit substrate 6 and the tester head 10. The tester head 10 may include the frequency signal transmission line 4 and a second DC signal transmission line 9 that may selectively contact a contact pad 32 of the DC signal transmission line 3. Therefore, as illustrated in FIG. 4, when the tester head 10 is lowered toward the circuit substrate 6, the second DC signal transmission line 9 may selectively contact the DC signal transmission line 3 through the contact pas 32, and the frequency signal transmission line 4 may selectively contact the third terminal 53.

The detachable instrument 7 may include any suitable coupling element, e.g., a screw, a bolt, a twist cap, and so on. For example, as illustrated in FIGS. 3 and 4, the detachable instrument 7 may include a coupling block 74. The coupling block 74 may engage with a hooking groove 72 of a socket mold 71 installed on the circuit substrate 6, as illustrated in FIG. 4, and may maintain the engaged state with the hooking groove 72 via the restoring force of a spring 73.

Hereinafter, a test processes using the electrical characteristics testing apparatus according to an embodiment will be described. First, referring to FIG. 1, to prepare for the DC characteristics test, an operator may bring down the tester head 10 toward the circuit substrate 6 to electrically connect the second DC signal transmission line 9 of the tester head 10 to the contact pad 32 of the circuit substrate 6, as illustrated in FIG. 2. Therefore, a DC signal may be applied to the second DC signal transmission line 9 to execute the DC characteristics test. At this time, the frequency signal transmission line 4 of the tester head 10 may be separated from the bar-type terminal 511, as illustrated in FIGS. 1-2.

Referring to FIG. 2, since the frequency signal transmission line 4 of the tester head 10 is separated from the bar-type terminal 511, the frequency signal transmission line 4 is not electrically connected to the bar-type terminal 511. Therefore, the bar-type terminal 511 may contact, e.g., only, the elastic terminal 521 due to the elastic bias of the elastic terminal 521, so the applied DC signal may pass from the second DC signal transmission line 9 through the contact pad 32, the DC signal transmission pattern 31 of the DC signal transmission line 3, the elastic terminal 521, the bar-type terminal 511, and the probe 2 to the test object 1 to test electrical characteristics thereof with respect to the DC signal.

To prepare for the frequency characteristics test, as illustrated in FIG. 3, the operator may assemble the detachable assembly 8 between the tester head 10 and the circuit substrate 6, and may mount the detachable assembly 8 onto the circuit substrate 6 by hooking the coupling block 74 onto the hooking groove 72, as illustrated in FIG. 4. As the detachable assembly 8 is mounted onto the circuit substrate 6, the conductive body 531a may be connected to the bar-type terminal 511 and the elastic terminal 521 may be contacted to the insulating body 531b, thereby blocking, i.e., disconnecting, the bar-type terminal 511 from being electrically connected to the elastic terminal 521.

Next, as illustrated in FIG. 4, the tester head 10 may be brought down toward the circuit substrate 6, so the frequency signal transmission line 4 of the tester head 10 may be connected to the conductive body 531a. Thus, the bar-type terminal 511 may be electrically connected to the frequency signal transmission line 4, while being electrically insulated from the DC signal transmission line 3. As such, the operator may conduct the frequency characteristics test having high precision and high reliability by applying an RF signal to pass through the frequency signal transmission line 4, the conductive body 531a of the third terminal 53, the bar-type terminal 511, and the probe 2 to the test object 1 without interactive interference between the RF signal and the blocked DC signal transmission line 3.

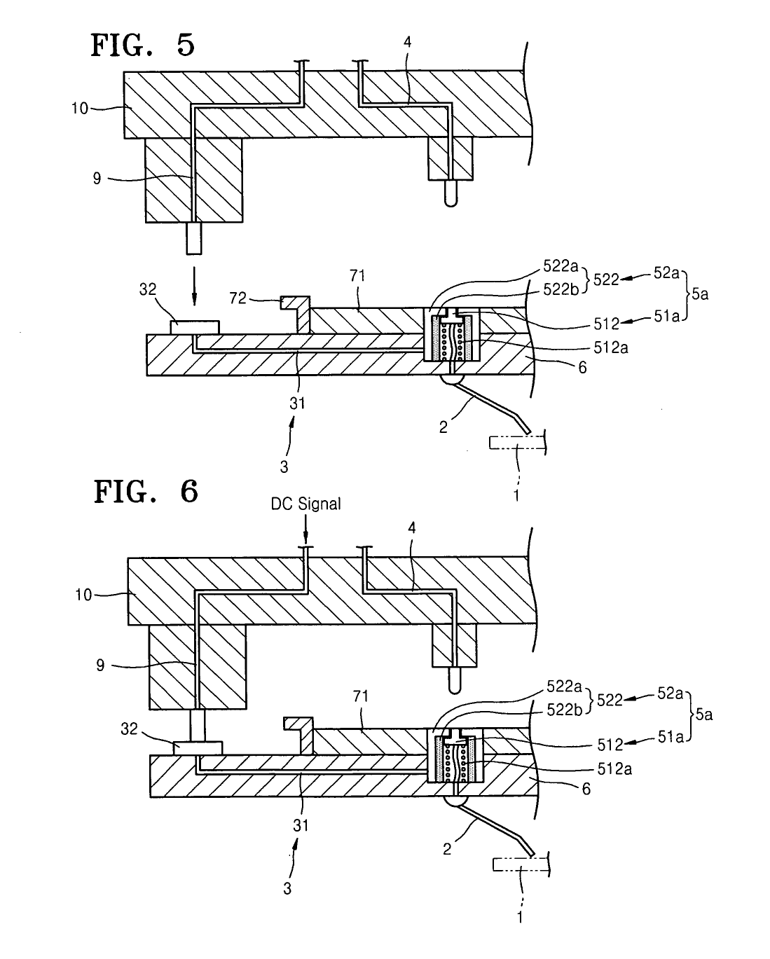

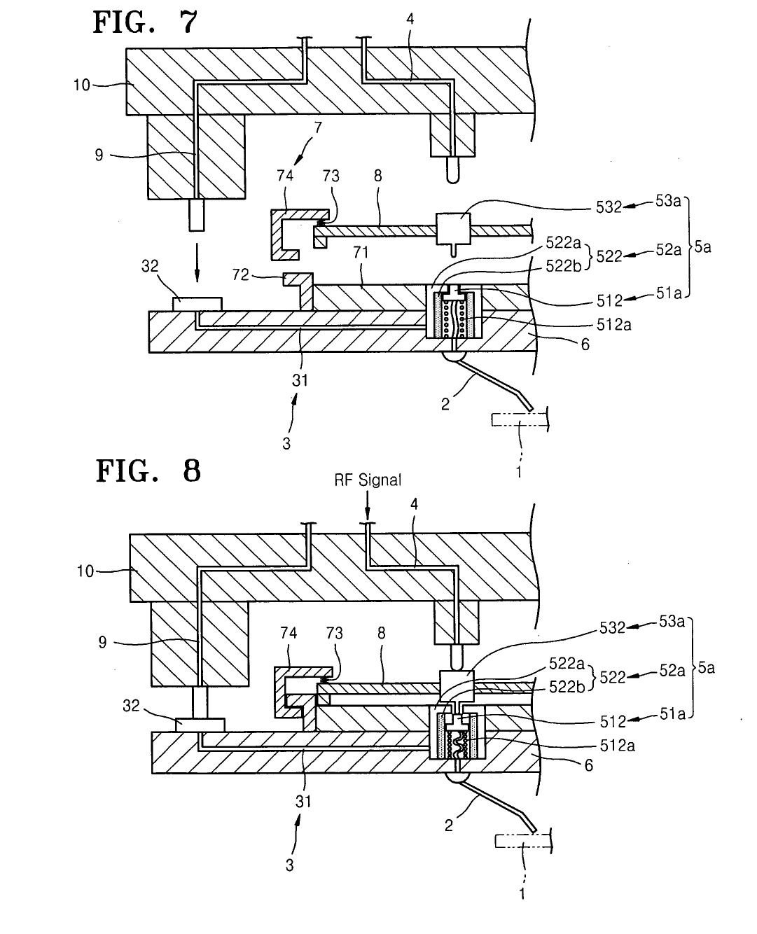

FIG. 5 illustrates a side cross-sectional view of an electrical characteristics testing apparatus in a preparation state of a DC characteristics test according to another embodiment. FIG. 6 illustrates a side cross-sectional view of the electrical characteristics testing apparatus of FIG. 5 in an execution state of the DC characteristics test. FIG. 7 illustrates a side cross-sectional view of the electrical characteristics testing apparatus of FIG. 5 in a preparation state of a frequency characteristics test. FIG. 8 illustrates a side cross-sectional view of the electrical characteristics testing apparatus of FIG. 7 in an execution state of the frequency characteristics test.

The electrical characteristics testing apparatus illustrated in FIGS. 5-8 is substantially the same as the apparatus described previously with reference to FIGS. 1-4, with the exception of having a different configuration of a line selection unit. Referring to FIGS. 5-8, a line selection unit 5a may include a first terminal 51a, a second terminal 52a, and a third terminal 53a.

The first terminal 51a may include a button-type terminal 512 that is electrically connected to the probe 2. The button-type terminal 512 may be positioned on an elastic spring 512a, so the button-type terminal 512 may be pressed, i.e., to be in a contracted state, or released, i.e., to be in an extended state, according to the elastic spring 512a.

The second terminal 52a may include a box-type terminal 522. The box-type terminal 522 may be electrically connected to the DC signal transmission pattern 31, and may surround the button-type terminal 512. For example, the box-type terminal 522 may include an electrical contact portion 522a on, e.g., directly on, an inner wall of the box-type terminal 522 and an insulating layer 522b on the electrical contact portion 522a, e.g., a portion of the electrical contact portion 522a may be between the insulating layer 522b and the inner wall of the box-type terminal 522. The box-type terminal 522 may be configured to have an opening therein, so the button-type terminal 512 may be surrounded by the electrical contact portion 522a and the insulating layer 522b.

For example, the electrical contact portion 522a of the box-type terminal 522 may be electrically connected to the DC signal transmission pattern 31, and may be on the inner sidewall and portions of an upper surface of the box-type terminal 522 to correspond to the button type terminal 512 in the extended state. In other words, when the elastic spring 512a is extended, e.g., as illustrated in FIG. 5, the button type terminal 512 may be electrically connected to the electrical contact portion 522a and the DC signal transmission pattern 31. The insulating layer 522b may correspond the button type terminal 512 in the contracted state. In other words, when the elastic spring 512a is contracted, e.g., as illustrated in FIG. 8, the button type terminal 512 may be electrically disconnected from the electrical contact portion 522a and the DC signal transmission pattern 31 via the insulating layer 522b.

The third terminal 53a may include a press terminal 532 that is installed on the detachable assembly 8. The press terminal 532 may be configured to press the button type terminal 512 when the detachable assembly 8 is attached to the circuit substrate 6 in order to set the button type terminal 512 in a contracted state.

Hereinafter, test processes using the electrical characteristics testing apparatus according to the present embodiment will be described. First, referring to FIG. 5, to prepare for the DC characteristics test, an operator may bring down the tester head 10 toward the circuit substrate 6. When the second DC signal transmission line 9 of the tester head 10 is electrically connected to the contact pad 32 of the circuit substrate 6, a DC signal may be applied to the second DC signal transmission line 9 to execute the DC characteristics test, as illustrated in FIG. 6.

Referring to FIG. 6, the frequency signal transmission line 4 of the tester head 10 may be separated from the button type terminal 512, i.e., no electrical connection therebetween. Instead, the button type terminal 512 may be in an extended state to be in contact with the electrical contact portion 522a of the box type terminal 522. Thus, the applied DC signal passes through the second DC signal transmission line 9, the contact pad 32, the DC signal transmission pattern 31 of the DC signal transmission line 3, the electrical contact portion 522a of the box type terminal 522 of the second terminal 52, the button type terminal 512 of the first terminal 52, and the probe 2 to the test object 1 to perform the test.

Referring to FIG. 7, to prepare for the frequency characteristics test, the operator may assemble the detachable assembly 8 between the tester head 10 and the circuit substrate 6. Also, as illustrated in FIG. 8, the coupling block 74 may be hooked onto the hooking groove 72 to mount the detachable assembly 8 onto the circuit substrate 6.

When the detachable assembly 8 is mounted onto the circuit substrate 6, the press terminal 532 and the button type terminal 512 may be electrically connected to each other. Simultaneously, the button type terminal 512 may be pressed by the press terminal 532, i.e., the elastic spring 512a may be contracted to set the button type terminal 512 in a contracted state, so the button type terminal 512 may be disconnected from the electrical contact portion 522a of the box type terminal 522. In other words, while the press terminal 532 presses the button type terminal 512, the button type terminal 512 may be in a contracted state, i.e., disconnected from the electrical contact portion 522a, so the electrical connection between the button type terminal 512 and the box type terminal 522 may be blocked by the insulating layer 522b.

Next, as illustrated in FIG. 8, the tester head 10 may be brought down toward the circuit substrate 6, so the frequency signal transmission line 4 of the tester head 10 may be electrically connected to the button type terminal 512 via the press terminal 532. Thus, an RF signal may be applied through the frequency signal transmission line 4, the press terminal 532, the button type terminal 512, and the probe 2 to the test object 1 to test the frequency characteristics of the test object with respect to the RF signal. As such, the frequency characteristics test may be conducted at high precision and high reliability without interactive interference between the RF signal and the DC signal transmission line 3 as described above.

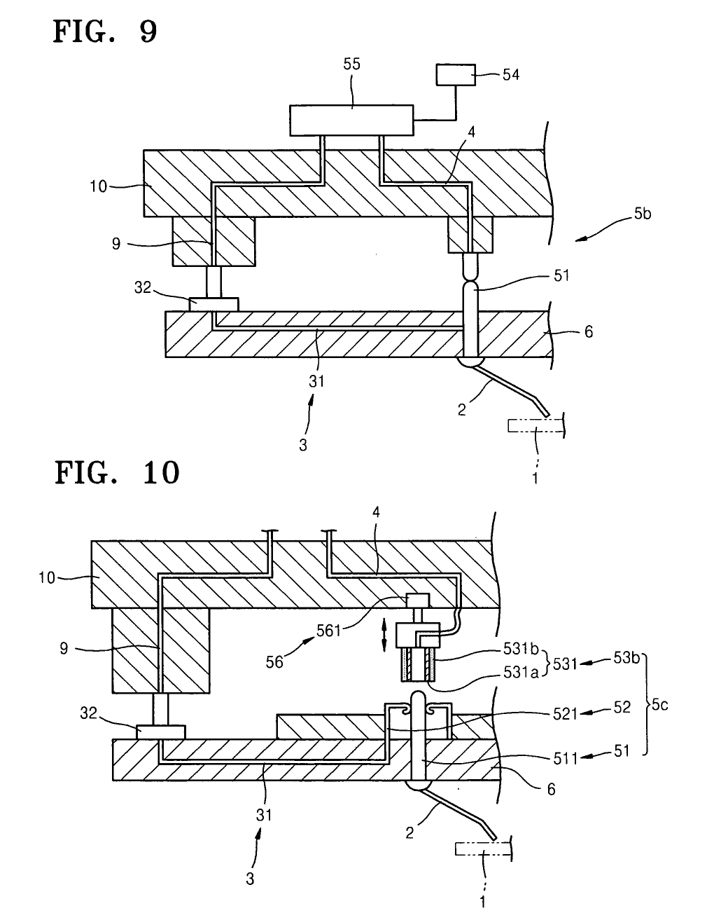

FIG. 9 illustrates a side cross-sectional view of an electrical characteristics test apparatus according to another embodiment. The electrical characteristics testing apparatus illustrated in FIG. 9 is substantially the same as the apparatus described previously with reference to FIGS. 1-4, with the exception of having a different configuration of a line selection unit. Referring to FIG. 9, a line selection unit 5b may include the first terminal 51, a selection circuit unit 55, and a control unit 54.

Referring to FIG. 9, the circuit unit 55 may receive a selection signal from the control unit 54, and may electrically activate one of the second DC signal transmission line 9 and the frequency signal transmission line 4. The selection circuit unit 55 may be any of various types of active devices, e.g., a semiconductor device, a microprocessor, a transistor, or a vacuum tube.

Accordingly, the operator may select either the group of DC signal transmission lines 3 and 9 or the frequency signal transmission line 4 via the control unit 54. In response, the selection circuit unit 55 may activate a corresponding test, thereby conducting a DC characteristics test or a frequency characteristics test.

FIG. 10 illustrates a side cross-sectional view of an electrical characteristics test apparatus according to another embodiment. The electrical characteristics testing apparatus illustrated in FIG. 10 is substantially the same as the apparatus described previously with reference to FIGS. 1-4, with the exception of having a different configuration of a line selection unit. Referring to FIG. 10, a line selection unit 5c may include the first terminal 51, the second terminal 52, a third terminal 53b, and a third terminal insertion unit 56.

As illustrated in FIG. 10, the third terminal 53b may be attached to the test head 10, i.e., without an assembly 8. In detail, the third terminal insertion unit 56 may selectively insert the third terminal 53b between the first terminal 51 and the second terminal 52. An actuator 561, e.g., that uses a hydraulic cylinder, a pneumatic cylinder, or a motor, may be used as the third terminal insertion unit 56.

Accordingly, as illustrated in FIG. 10, when executing a DC characteristics test, the third terminal 53b may be raised, such that the probe 2 may be connected to the DC signal transmission line 3 via the first terminal 51 and the second terminal 52. Similarly, when executing a frequency characteristics test, the third terminal 53b may be brought down, such that the conductive body 531a of the third terminal 53b may be electrically connected to the first terminal 51 and the frequency signal transmission line 4. Simultaneously, the probe 2 may be electrically disconnected from the DC signal transmission line 3 by using the insulating body 531b.

An electrical characteristics test apparatus according to example embodiments may test both DC characteristics and frequency characteristics of a device in a single apparatus, thereby reducing manufacturing costs of the testing apparatus. Further, interference between a DC signal transmission line and a frequency signal transmission line in the test apparatus may be prevented, thereby improving the performance and reliability of the test apparatus. In addition, since the tested device is connected to the electrical characteristics test apparatus only once, i.e., multiple electrical characteristics tests may be performed while the device is connected to the test apparatus, testing time may be substantially reduced. In contrast, when separate conventional apparatuses for testing DC and frequency characteristics are used, separate installation and disconnection of a tested device from each testing apparatus may be cumbersome and time consuming.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An apparatus for testing electrical characteristics, comprising:
a probe configured to contact a test object;
a first direct current (DC) signal transmission line configured to transmit a DC signal to the probe;
a frequency signal transmission line configured to transmit a frequency signal to the probe; and
a line selection unit configured to selectively connect only one of the frequency signal transmission line and the DC signal transmission line to the probe at a time in accordance with a selected test.

2. The apparatus as claimed in claim 1, wherein the line selection unit includes:
a first terminal electrically connected to the probe;
a second terminal electrically connected between the DC signal transmission line and the first terminal; and
a third terminal electrically connected to the frequency signal transmission line, the third terminal being configured to electrically contact the first terminal and simultaneously to block the electrical connection between the first terminal and the second terminal.

3. The apparatus as claimed in claim 2, wherein:
the first terminal is a bar-type terminal in a circuit substrate, the probe being installed on the circuit substrate,
the second terminal is an elastic terminal electrically connected to a DC signal transmission pattern in the circuit substrate, the second terminal being configured to elastically contact the bar-type terminal, and
the third terminal is a pipe type terminal on a detachable assembly, the detachable assembly being connected to the circuit substrate, the third terminal being selectively inserted between the bar-type terminal and the elastic terminal to block electrical connection between the bar-type terminal and the elastic terminal, and the third terminal including an insulating body corresponding to the elastic terminal and a conductive body corresponding to the bar-type terminal so that the third terminal is electrically connected to the bar-type terminal.

4. The apparatus as claimed in claim 2, wherein:
the first terminal is a button type terminal in a circuit substrate, the probe being installed on the circuit substrate, and the button type terminal being configured to extend or contract according to an elastic spring,
the second terminal is a box type terminal electrically connected to a DC signal transmission pattern in the circuit substrate via an electrical contact portion on an inner wall of the box type terminal, the box type terminal surrounding the button type terminal, and the electrical contact portion being electrically connected to the button type terminal when the button type terminal is extended, and
the third terminal is a press terminal on a detachable assembly, the detachable assembly being attached to the circuit substrate, and the third terminal being configured to selectively press and contract the button type terminal so as to disconnect the button type terminal from the electrical contact portion of the second terminal via an insulating layer in the second terminal.

5. The apparatus as claimed in claim 2, wherein the first terminal and the second terminal are in a circuit substrate, and the third terminal is on a detachable assembly configured to attach to the circuit substrate via a detachable instrument.

6. The apparatus as claimed in claim 5, further comprising a tester head configured to selectively connect to the circuit substrate and the detachable assembly, the tester head including the frequency signal transmission line and a second DC signal transmission line contacting a contact pad of the first DC signal transmission line.

7. The apparatus as claimed in claim 5, wherein the detachable instrument is a coupling block configured to engage with a hooking groove of a socket mold installed on the circuit substrate, the detachable instrument being configured to maintain the engaged state with the hooking groove via a spring.

8. The apparatus as claimed in claim 2, further comprising a third terminal insertion unit configured to selectively insert the third terminal between the first terminal and the second terminal.

9. The apparatus as claimed in claim 8, wherein the third terminal insertion unit is an actuator including a hydraulic cylinder, a pneumatic cylinder, or a motor.

10. The apparatus as claimed in claim 1, wherein the line selection unit includes a selection circuit unit and a control unit, the selection circuit unit being configured to receive a selection signal from the control unit in accordance with the selected test, and to electrically activate the DC signal transmission line or the frequency signal transmission line.

11. The apparatus as claimed in claim 1, wherein the line selection unit includes:
a first terminal through a circuit substrate, a first end of the first terminal being electrically connected to the probe, and a second end of the first terminal being selectively connected to the frequency signal transmission line; and
a DC signal transmission pattern in the circuit substrate, the signal transmission pattern being selectively connected to the first terminal, only one of the frequency signal transmission line and the DC signal transmission pattern being electrically connected to the first terminal at a time in accordance with the selected test.

12. The apparatus as claimed in claim 11, further comprising:
a second terminal in the circuit substrate electrically connected to the DC signal transmission pattern and the first terminal; and
a third terminal configured to selectively disconnect the electrical connection between the first and second terminals in accordance with the selected test, the third terminal being configured to connect the first terminal to the frequency signal transmission line upon electrical disconnection between the first and second terminals.

13. The apparatus as claimed in claim 12, wherein the third terminal includes a conductive layer and an insulting layer, the insulating layer being between the first and second terminals when the first terminal and the conductive layer of the third terminal electrically contact each other.

14. The apparatus as claimed in claim 12, wherein the second terminal includes a conductive tube and an insulting tube concentric to each other, the insulating tube being between the first terminal and the conductive tube of the second terminal when the first and third terminals electrically contact each other.

15. The apparatus as claimed in claim 12, wherein one of the second and third terminals includes an insulating layer configured to electrically disconnect the first and second terminals.

16. The apparatus as claimed in claim 12, wherein the third terminal is on an opposing surface than the first and second terminals.
